(19) United States
(12) Patent Application Publication
(10) Pub. No.: US 2026/0280490 A1
(43) Pub. Date: Sep. 17, 2026

(54) DUAL-DRIVE HIGH-EFFICIENCY WIDE-BAND COMPACT DOHERTY POWER AMPLIFIER

(71) Applicant: EMTAR Technologies Inc., Richmond (CA)

(72) Inventors: Xiang LI, Kanata (CA); Min-Yu HUANG, Richmond (CA)

(73) Assignee: EMTAR Technologies Inc., Richmond (CA)

(21) Appl. No.: 19/673,200

(22) Filed: May 11, 2026

Related U.S. Application Data
(63) Continuation of application No. PCT/IB2025/052449, filed on Mar. 6, 2025.
(60) Provisional application No. 63/562,222, filed on Mar. 6, 2024.

(51) Int. Cl. H03F 1/02; H03F 3/195; H03F 3/24

(52) U.S. Cl. CPC H03F 1/0288; H03F 3/195; H03F 3/245; H03F 2200/318; H03F 2200/451; H03F 2203/21139; H03F 2203/21142

(57) ABSTRACT

A power amplifier circuit includes a carrier amplifier branch with a carrier driver cell and a carrier power amplifier cell, a peaking amplifier branch with a peaking driver cell with a peaking power amplifier cell, and multiple interstage matching networks. The carrier and peaking driver cells regulate currents flowing through the carrier and peaking power amplifier cells, respectively. A pre-driver cell coupled to the carrier and peaking driver cells respectively via interstage matching networks switches off a third current flowing through the peaking amplifier branch when the peaking power cell operates below a threshold power level. An input power dividing network coupled to the carrier and peaking amplifier branches divides an input RF signal between the branches. An output combiner circuit including at least one parasitic capacitance is coupled to the two amplifier cells, combining output signals from them to amplify the RF signal.

### CROSS-REFERENCE TO RELATED APPLICATIONS

This application is a continuation of International Application No. PCT/IB2025/052449, filed Mar. 6, 2025, and entitled “DUAL-DRIVE HIGH-EFFICIENCY WIDE-BAND COMPACT DOHERTY POWER AMPLIFIER,” which claims the benefit of priority to U.S. Provisional Patent Application No. 63/562,222 filed Mar. 06, 2024, entitled “Dual-Drive High-Efficiency Wide-Band Compact Doherty Power Amplifier,” which are assigned to the assignee hereof. The disclosure of the prior Applications are considered part of and are incorporated by reference in this Patent Application.

### FIELD OF THE DISCLOSURE

Various embodiments relate to a radio-frequency (RF) amplifier.

### BACKGROUND

A Doherty power amplifier (also called a “Doherty amplifier” or “Doherty PA”) is a type of RF amplifier that has two amplifier stages – one for low-power signals and one for high-power signals. The amplifier stage for low-power signals is commonly called the “carrier amplifier stage” and involves a carrier amplifier. The amplifier stage for high-power signals is commonly called the “peaking amplifier stage” and involves a peaking amplifier. The dual-stage approach – where the carrier amplifier handles low-power signals and the peaking stage is only brought when needed to handle high-power signals – offers benefits, as a larger range of signals can be accommodated with high efficiency. Due to these benefits, Doherty amplifiers are increasingly being used in base stations (e.g., mobile phone base stations) and other radio communication systems.

In a Doherty amplifier, the carrier and peaking amplifiers are usually biased differently. The carrier amplifier is usually biased in Class AB or Class B, while the peaking amplifier is usually biased in Class C – which only conducts at half of the signal cycle and cuts in on high signal peaks that are indicative of high-output power demands. Such a design allows Doherty amplifiers to achieve a high level of efficiency, especially at lower power levels.

However, a Doherty amplifier can suffer from bandwidth limitations due to its impedance network (and more specifically, its one-quarter wavelength transmission lines that is used as an impedance inverter). To address this issue, the impedance network could be redesigned in an effort to broaden bandwidth operation, but that would likely require substantial circuit area that may not be available.

### BRIEF DESCRIPTION OF THE DRAWINGS

FIG. 1 shows the topology of a conventional Doherty amplifier.

FIG. 2 shows the generalized topology of a three-stage, dual-drive Doherty amplifier, as proposed and described herein.

FIGS. 3A and 3B show generalized topologies of output combiner circuits that could be implemented as part of the three-stage, dual-drive Doherty amplifier shown in FIG. 2.

FIGS. 4A, 4B, and 4C show specific examples of output combiner circuits that could be implemented as part of a three-stage, dual-drive Doherty amplifier.

FIGS. 5A and 5B show specific examples of networks for a peaking branch that could be implemented as part of a conventional Doherty amplifier and a three-stage, dual-drive Doherty amplifier, respectively.

FIGS. 6A and 6B show the bandwidth differences between a traditional output network and a network for a peaking branch with a center frequency of 1 gigahertz (GHz) that could be implemented as part of a three-stage, dual-drive Doherty amplifier.

FIGS. 7A and 7B show the bandwidth differences between a traditional output network and a network for a peaking branch with a center frequency of 3.75 GHz that could be implemented as part of a three-stage, dual-drive Doherty amplifier.

FIGS. 8A and 8B show the bandwidth differences between a traditional output network and a network for a peaking branch with a center frequency of 10 GHz that could be implemented as part of a three-stage, dual-drive Doherty amplifier.

FIG. 9 plots fractional bandwidths versus frequency for a traditional output network and a network that could be implemented as part of a three-stage, dual-drive Doherty amplifier.

FIG. 10 plots fractional bandwidth ratios between a traditional output network and a network that could be implemented as part of a three-stage, dual-drive Doherty amplifier.

FIG. 11 shows a schematic example of a three-stage, dual-drive Doherty amplifier.

FIG. 12 shows another schematic example of a three-stage, dual-drive Doherty amplifier.

FIG. 13 shows an example layout distribution of a compact three-stage, dual-drive Doherty amplifier.

FIG. 14 shows another example layout distribution of a compact three-stage, dual-drive Doherty amplifier.

Various features of the three-stage, dual-drive Doherty amplifier described herein will become more apparent to those skilled in the art from a study of the Detailed Description in conjunction with the drawings. Various embodiments are shown in the drawings for the purpose of illustration. However, those skilled in the art will recognize that alternative embodiments may be employed without departing from the principles of the invention. Accordingly, while specific embodiments are shown in the drawings, the three-stage, dual-drive Doherty amplifier is amendable to various modifications.

### DETAILED DESCRIPTION

Introduced here are embodiments of a three-stage, dual-drive Doherty amplifier, which can be used to amplify wireless RF signals by converting direct-current (DC) energy into RF energy. For convenience, the dual-drive Doherty amplifier introduced here may simply be called the “power amplifier circuit” or “power amplifier.” These embodiments can be used in base stations, satellite communication systems, radar systems, point-to-point microwave link devices, wireless power transfer applications, multiple-input, multiple-output (MIMO) systems, backhaul networks, internet of things (IoT) devices, wireless communications systems, microwave systems, and the like. Accordingly, these embodiments may be suitable for various applications, including those related to defense and aerospace and involving high-bandwidth Wi-Fi, Light Detection and Ranging (LiDAR), and the like.

Wireless communication systems are developed from generation to generation to accommodate the increasing demands of higher and higher data rates, ending up with different standards at different frequency bands. Most of the time, the infrastructure needs to be upgraded to fulfill these standards, which can be very expensive. Sometimes, several subsystems are integrated together to cover several frequency bands for different applications, which can increase the cost dramatically. A cost-effective way to address these challenges is to design a single system that can be used in different frequency bands. As the last stage on the transmitter in the wireless communication system, power amplifiers are used to cover these different frequency bands.

Moreover, green energy and low carbon emission are global needs at present. Thus, achieving low energy cost is a goal for wireless communication systems and microwave systems. In such systems, the power amplifier usually dominates the power consumption. The ratio of the RF energy that is produced as output to the DC energy that is supplied as input is defined as the efficiency. The lower the efficiency, the more power consumed by the power amplifier. This consumed power is converted into heat, which is generally dissipated by expensive cooling systems to maintain a certain temperature. Thus, to reduce the energy costs and the cooling costs, higher efficiency power amplifiers are needed.

To efficiently use spectrum resources, complex modulation methods, such as quadrature amplitude modulation (QAM), and multiplexing methods, such as orthogonal frequency division multiplexing (OFDM), can be used. Such methods can provide higher peaking-to-average power ratios (PAPR). Although some power amplifiers have a higher efficiency at peak output power, the efficiency can degrade significantly at output back-off (OBO). High PAPR means that these power amplifiers operate with low average efficiency most of the time for modulated signals.

Different methods and topologies can be used to improve the average efficiency. For example, a conventional Doherty amplifier that includes a carrier amplifier and a peaking amplifier may be used. The carrier amplifier is usually biased in Class B or Class AB, while the peaking amplifier is usually biased in Class C. The output of the carrier and peaking amplifiers are combined with one-quarter wavelength transmission lines and offset lines. However, the bandwidth of conventional Doherty amplifiers can be limited by these transmission lines and offset lines that occupy significant space on the printed circuit board (PCB).

Moreover, compact size radio units are desired for applications such as small cellular base stations (also called “cell sites”) and satellite wireless communication systems. However, designing power amplifiers using conventional methods on PCBs in tight spaces poses challenges. Monolithic microwave integrate circuits (MMICs) can be used to reduce the size of passive circuit components (also called “passive circuit elements”) that receive energy but do not amplify or generate it. Synthesis techniques that utilize gallium nitride (GaN) could also be used to reduce the size of active circuit components (also called “active circuit elements”) that generate energy. A power amplifier is one example of an active circuit component. However, the cost of implementing an MMIC GaN power amplifier tends to be high, especially for high-gain and high-power applications, and therefore impractical for many applications. Besides, combining power supply on a compact circuit can introduce additional stability issues, which can reduce the reliability of the power amplifier.

In the present disclosure, several different designs of dual-drive Doherty amplifiers and methods for designing and implementing the same are disclosed. These dual, drive Doherty amplifiers address the aforementioned challenges by implementing separate driver stages for the carrier and peaking paths, allowing the peaking driver to remain inactive during back-off, thereby improving efficiency. An output combiner circuit that utilizes parasitic capacitance and has a T-shape topology may also be implemented to achieve wider bandwidths while occupying a smaller area of the PCB. Further, a hybrid multi-chip approach could be employed in which GaN active circuit components and gallium arsenide (GaAs) passive circuit components are used to reduce cost while maintaining performance. As further discussed below, the dual-drive architectures introduced here may share biasing components between the driver and power stages in each path, thereby reducing the total count of components needed for the Doherty amplifier. Stability networks may also be implemented between the driver and power stages to prevent oscillation from shared biasing components. In some embodiments, the output combiner circuit leverages inherent capacitances as part of the matching network. Further, strategic integrated circuit (also called “microchip” or simply “chip”) placement can be implemented to separate high-power devices to improve thermal management.

With the dual-drive architectures introduced here, high efficiency across a wide bandwidth can be achieved while the size and cost are reduced in comparison to the architectures of conventional Doherty amplifiers. For example, the hybrid approach can balance the higher-power density of GaN active circuit components with the lower cost of GaAs passive circuit components. Thermal management can be achieved through strategic chip placement to reduce cooling requirements. Moreover, the multi-chip implementations described below may not only yield improved manufacturability, but also yield in comparison to fully integrated MMIC solutions. Bonding wire connections between different chips can be used to provide flexibility in design optimization while maintaining smaller size. Accordingly, the dual-drive architectures can deliver high performance – all in a compact form factor that is well suited for space-constrained applications.

In some implementations, a dual-drive Doherty amplifier includes separate carrier and peaking branches, each with its own driver stage sharing biasing with a corresponding power stage. The carrier branch may bias to Class AB, while the peaking branch may bias to Class C. Stability networks or individual stability circuits that include parallel resistor and capacitor (RC) circuits can be implemented to prevent oscillation from the shared biasing arrangement. An interstage power dividing network (also called an “interstage power divider”) can feed the driver stages, with the peaking driver remaining inactive during back-off operation to improve efficiency. In some implementations, the output combiner circuit has a compact T-shape topology that leverages the parasitic capacitances of the power transistors. A shunt inductor at the carrier amplifier drain can provide both impedance matching and DC bias feed. The peaking path can use a series capacitor and shunt component (e.g., an inductor) arrangement to present the proper impedance during both low- and high-power operation. This topology can achieve wider bandwidths than conventional one-quarter wavelength transmission lines while reducing circuit area.

In some implementations, a dual-drive Doherty amplifier is implemented using a hybrid multi-chip approach with GaN active circuit components (e.g., transistors) and GaAs passive circuit components (e.g., networks). The carrier and peaking power transistors can be physically separated to reduce thermal coupling. Input, interstage, and output matching networks can be implemented on separate GaAs chips that are connected via bonding wires. This modular approach optimizes cost and thermal management while maintaining small size through strategic chip placement.

The dual-drive Doherty amplifier architecture provides several advantages over conventional Doherty amplifier architectures. By using separate driver stages that share biasing with their respective power stages, the dual-drive Doherty amplifier introduced here can achieve higher efficiency during back-off operation since the peaking driver remains inactive. The shared biasing reduces the total number of circuit components, while the stability networks prevent oscillation. This approach improves average efficiency when handling modern communication signals with high peak-to-average power ratios. The output combiner circuit and hybrid multi-chip implementation deliver additional benefits. The T-shape combining topology leverages device parasitics to achieve wider bandwidths in smaller areas compared to traditional matching network plus transmission line approaches. Using GaN for active devices and GaAs for passive networks reduces implementation cost while maintaining performance. Accordingly, in some embodiments, all of the matching networks of the dual-drive Doherty architecture may be passive networks that are implemented using GaAs, silicon, or another suitable substrate material. The physical separation of high-power devices improves thermal management, reducing cooling requirements and operating costs. The modular implementation improves manufacturability while bonding wire connections maintain flexibility in optimization.

The dual-drive Doherty amplifier architecture described here can also reduce power consumption through selective activation of amplifier stages. During power back-off operation, which can occur frequently with modern communication signals, the peaking driver and amplifier remain inactive. This reduces wasted power consumption in the peaking path during low-power operation. The shared biasing approach between driver and power stages also reduces the number of power supply components needed, reducing conversion losses in the biasing network.

The output combiner circuit contributes to power savings through improved impedance matching and reduced losses. By leveraging parasitic capacitances in the T-shape topology, the dual-drive Doherty amplifiers introduced here are able to achieve more-efficient power combining while reducing resistive losses that would otherwise become heat. The wider bandwidth capability also improves efficiency across operating frequencies, reducing the need for multiple amplifiers and associated power overhead. The thermal management aspects reduce cooling power requirements. Physical separation of high-power devices – plus the implementation of GaN and GaAs circuit components – allows for lower operating temperatures without extensive cooling systems. In contrast, conventional Doherty amplifier architectures commonly require energy-intensive cooling solutions. However, the improved thermal efficiency of the dual-drive Doherty amplifiers introduced here reduces cooling power needs without negative impacting performance. The combination of improved electrical efficiency and reduced cooling requirements results in lower overall power consumption and reduced environmental impact.

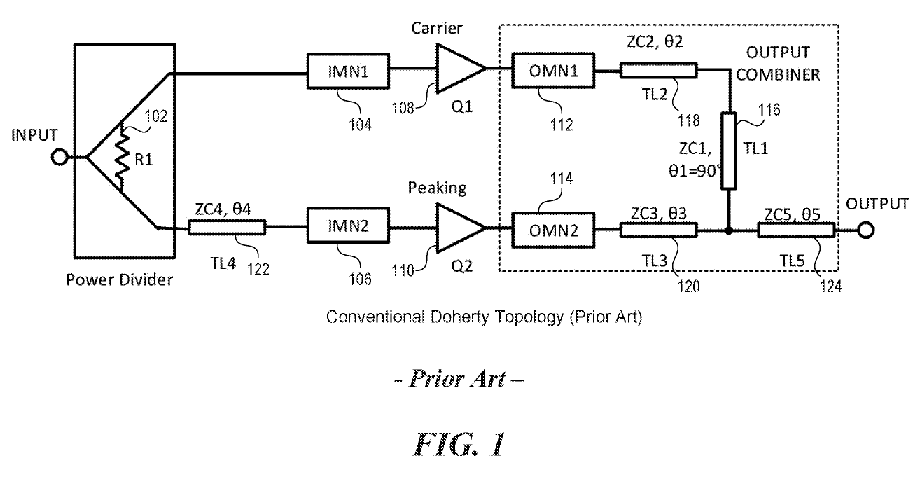

FIG. 1 shows the topology of a conventional Doherty amplifier including two branches shown oriented horizontally. The upper branch including components 104, 108, 112, and 118 is representative of the carrier branch and the lower branch including components 122, 106, 110, 114, and 120 is representative of the peaking branch. In embodiments, each branch can have one power amplifier cell (sometimes called “PA cells”). A carrier power amplifier cell can include an active device Q1 (108). In some embodiments, Q1 (108) can be biased in class-AB. Further, the input of Q1 (108) can be matched to a reference impedance (which is typically 50 Ohm) with an input matching network IMN1 (104). The output of Q1 (108) can be matched to a reference impedance with an output matching network OMN1 (112).

In embodiments, similar to the carrier power amplifier cell, a peaking power amplifier cell can have one active device Q2 (110) that is biased in Class C, one input matching network IMN2 (106), and one output matching network OMN2 (114). The carrier power amplifier cell and peaking power amplifier cell can be combined using a one-quarter wavelength transmission line TL1 (116) that can be configured as an impedance inverter. An offset line TL2 (118) can be inserted between the carrier power amplifier cell and TL1 (116) to adjust the load impedances. In embodiments, an offset line TL3 (120) can be inserted between the peaking power amplifier cell and the joint position to transfer the output impedance of the peaking power amplifier cell to a quasi-open-circuit. A delay line TL4 (122) can be added at the input of the peaking power amplifier cell to align the phase between the carrier branch and peaking branch. The input RF signal can be divided among the carrier branch and peaking branch using an interstage power dividing circuit (also called an “interstage power divider”) including a resistor R1 (102). Further, the impedance at the joint position can be transformed into the reference impedance by transmission line TL5 (124). Due to the intrinsic parasitic capacitances of the active devices, matching networks, and transmission lines, the bandwidth of conventional Doherty amplifiers is generally limited.

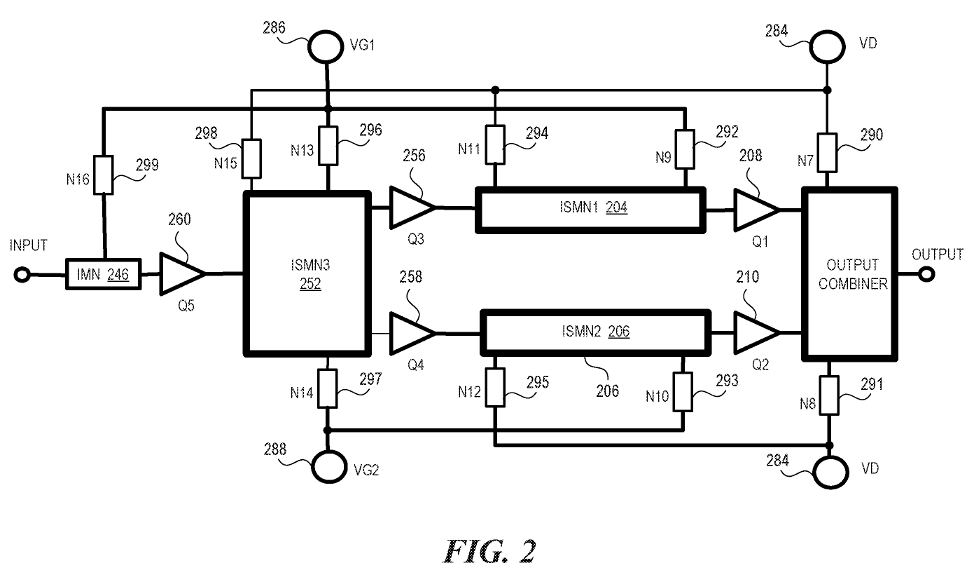

To increase the gain, driver stages can be added to the input of the Doherty amplifier. However, a single-driver amplifier cascading the Doherty amplifier would lead to low average efficiency, since more than half of the output power of the driver would be wasted on the peaking branch at power back-off. Accordingly, a three-stage, dual-drive Doherty topology is proposed herein, an example of which is shown in FIG. 2. Along the carrier branch, there may be a carrier driver stage that comprises active device Q3 and an interstage matching network ISMN1 at its output. The output of active device Q3 can be biased with DC voltage VD through network N11. Meanwhile, the output of active device Q1 can be biased with the same DC voltage VD through network N7. The input of the active device Q3 and the input of the active device Q1 can be biased with the same DC voltage VG1 through inductors N9 and N13, respectively.

Similar to the carrier branch, the peaking branch may include a peaking driver stage that comprises active device Q4 and an interstage matching network ISMN2 at its output that is added before the peaking power amplifier cell. As shown in FIG. 2, these components may share the same input biasing DC voltage VG2 through respective networks N10, N14. Output biasing DC voltage VD can also be shared by active devices Q4, Q2 through respective networks N8, N12. Because the peaking driver stage does not consume power at power back-off, the efficiency of the dual-driver Doherty amplifier is higher than that of a single-drive Doherty amplifier.

In some embodiments, a pre-driver stage is used to further boost the gain. The pre-driver stage may comprise an active device Q5, input matching network IMN, and output interstage matching network ISMN3, which can also serve as a power splitter. The active device Q5 can share the same input biasing DC voltage VG1 and output biasing DC voltage VD as the carrier branch. Meanwhile, N7 – N16 may be different biasing networks that comprise inductors, transmission lines, resistors, bypass capacitors, or different combinations thereof.

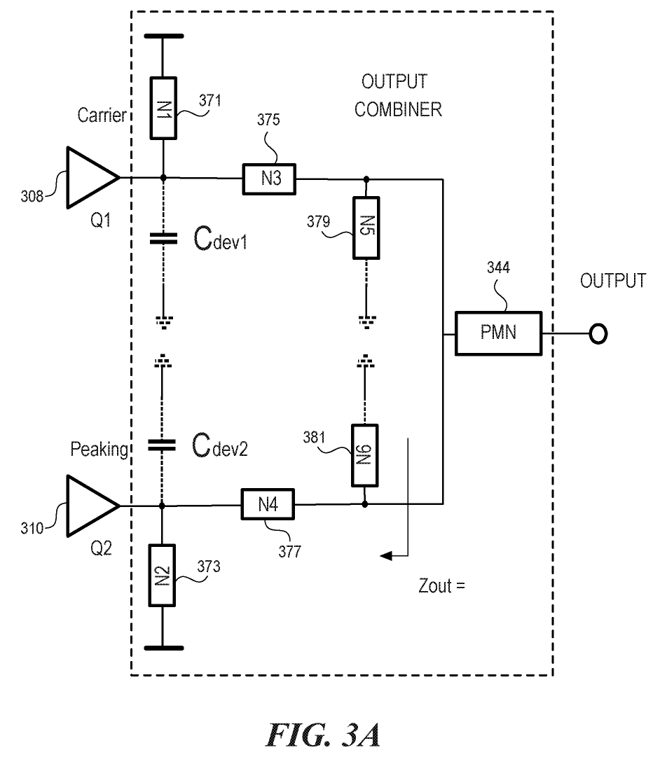

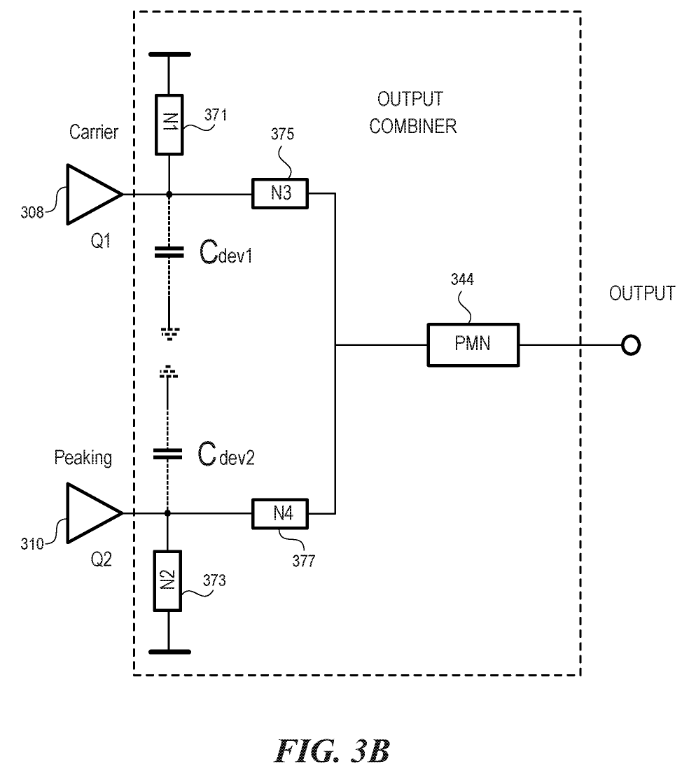

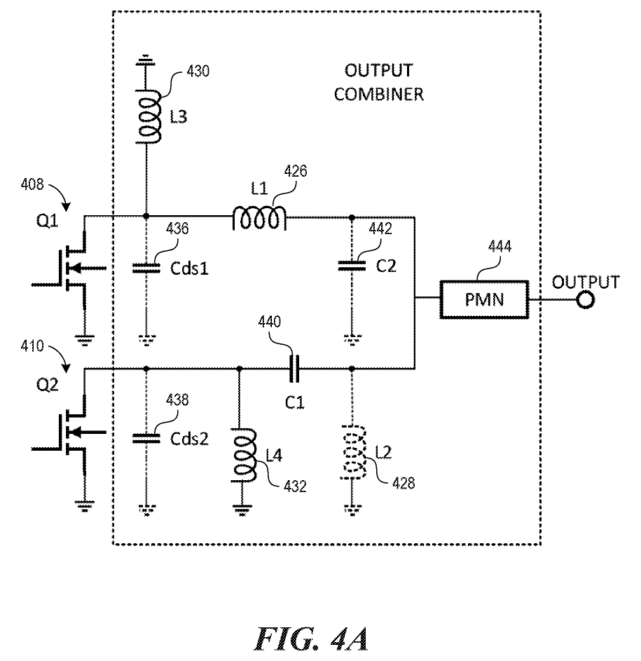

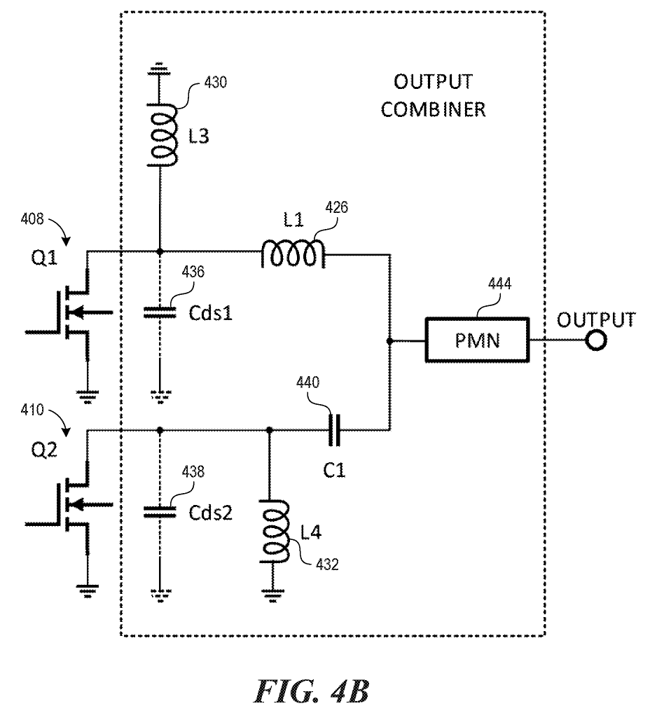

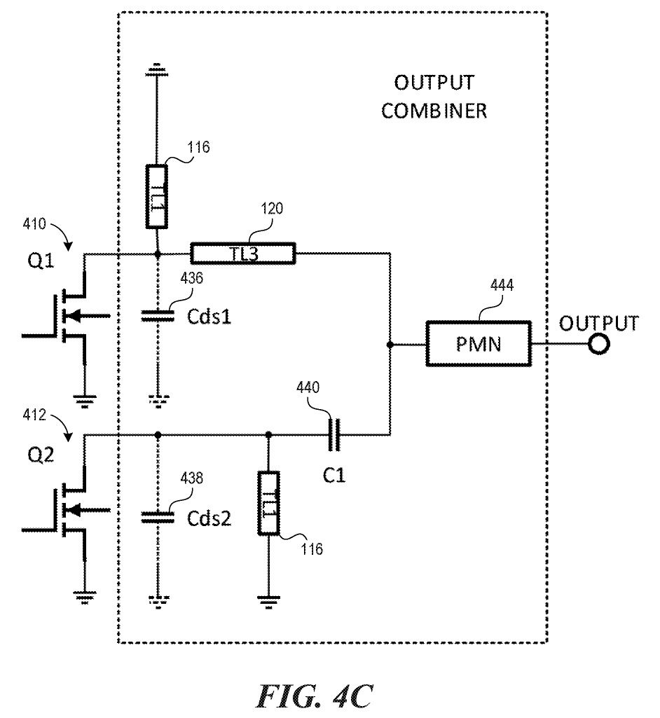

To reduce the size and extend the bandwidth of the output combiner circuit, a compact matching combiner circuit could be implemented. An example of a compact matching combiner circuit is shown in FIGS. 3A and 3B. The active devices Q1 and Q2 are combined with several simple parts N1 – N6, which can be inductors, capacitors, or resistors. The combination of N1, N3, N5, and the intrinsic parasitic C_{dev1} can be equivalent to an impedance invertor with a phase shift of 90 degrees. The combination of N2, N4, N6, and the intrinsic parasitic C_{dev2} can be equivalent to an offset line with a phase shift of 180 degrees. The post-matching network PMN can be any low-pass, high-pass, or band-pass network that can be used to transform the standard load to the target load impedance. N5 and N6 can be absorbed by the post-matching network PMN as shown in FIG. 3B. One example is shown in FIG. 4A.

Typically, a π-shape capacitor-inductor-capacitor (CLC) network can be used that is equivalent to an impedance invertor with a phase shift of 90 degrees. In some embodiments, when the parameter of the intrinsic parasitic capacitance Cds1 (436) in Q1 (408) is larger, a shunt inductor L3 (430) can be added to partially compensate for Cds1 (436). Thus, a more-compact impedance invertor can be implemented using the shunt inductor L3 (430) (which can also be used as a drain supply DC feeding component), the parasitic capacitance Cds1 (436), a series inductor L1 (426), and a shunt capacitor C2 (442). The offset line in the peaking branch can be replaced with compact π-shape inductor-capacitor-inductor (LCL) network, which includes the parasitic capacitance Cds2 (438), shunt inductor L4 (432), series capacitor C1 (440), and shunt inductor L2 (428). In some embodiments, shunt capacitor C2 (442) and shunt inductor L2 (428) can be absorbed by a post-matching network (PMN) (444). Further, the output combiner circuit can include a shunt inductor L3 (430) on the drain of Q1 (408), a shunt inductor L4 (432) on the drain of Q2 (410), a series inductor L1 (426), a parallel capacitor C2 (442) and a post-matching network (444), as shown in FIG. 4B. The shunt inductors L3 (430) and L4 (432) can be replaced with transmission lines, as shown in FIG. 4C.

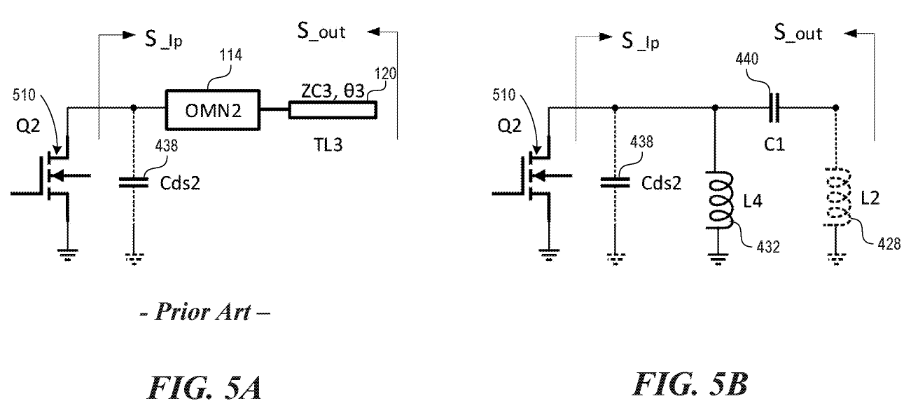

FIGS. 5A and 5B show specific examples of networks for a peaking branch that could be implemented as part of a conventional Doherty amplifier and a three-stage, dual-drive Doherty amplifier, respectively. Embodiments that do not and do utilize the dual-drive architecture described here are shown. When the dual-drive architecture is implemented, the topology of the combining network (output combiner circuit) is simpler and smaller compared to the architecture of a conventional Doherty amplifier, and hence the achieved bandwidths are higher than for a conventional Doherty amplifier.

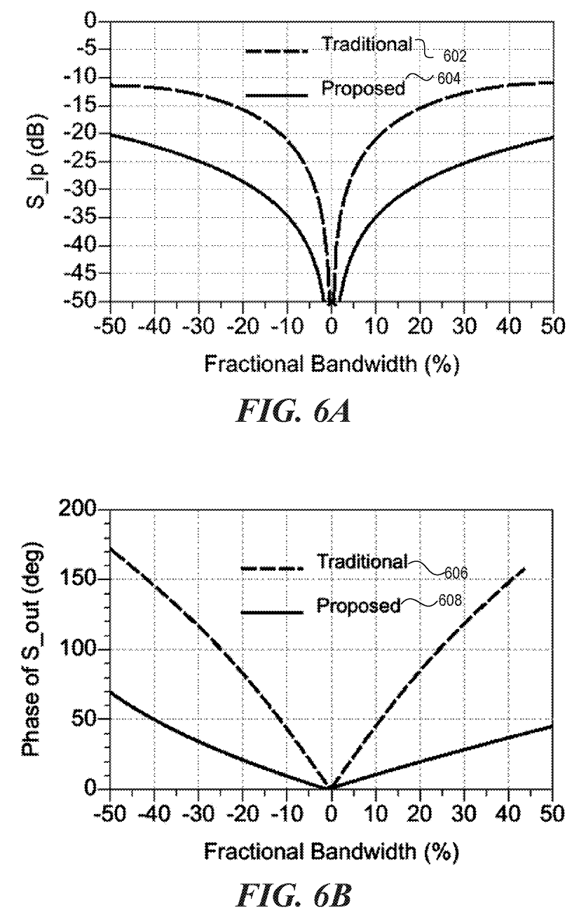

FIGS. 6A and 6B show the bandwidth differences between a traditional output network and a network for a peaking branch with center frequency of 1 GHz that could be implemented as part of a three-stage, dual-drive Doherty amplifier. The fractional bandwidth achieved is proportional to many factors such as center operating frequency, optimum load impedance, parasitic capacitance, etc. As an example, for a given parasitic capacitance of 4.6 picofarads (pF) and a target optimum load of 15 Ohm, the load return loss S_lp can be obtained using a traditional output network (602) and the disclosed network (604) for a center operating frequency of 1 GHz, as shown in FIG. 6A, and the output return loss S_out can be obtained using a traditional output network (606) and the disclosed network (608) as shown in FIG. 6B.

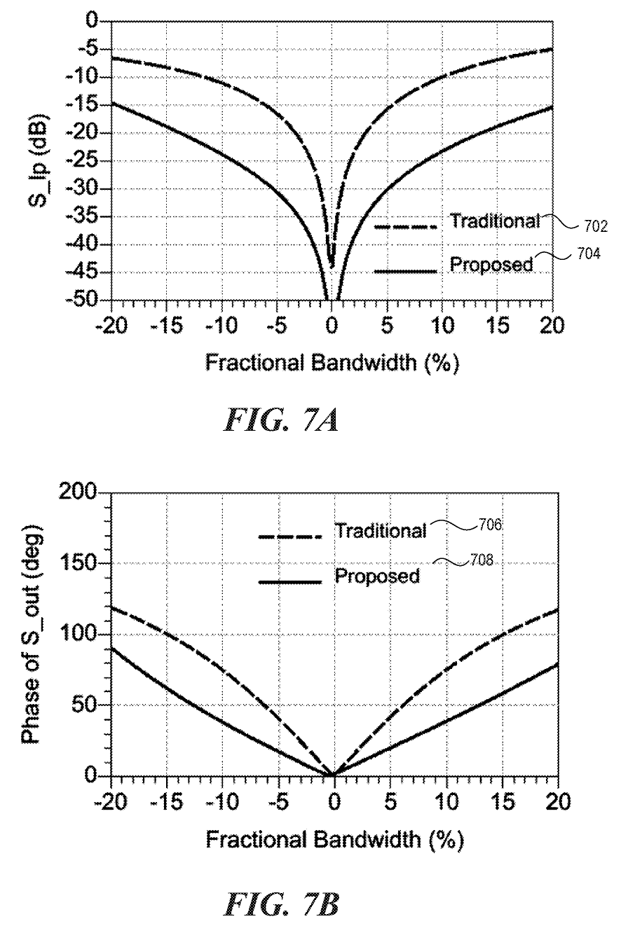

FIGS. 7A and 7B show the bandwidth differences between a traditional output network and a network for a peaking branch with a center frequency of 3.75 GHz that could be implemented as part of a three-stage, dual-drive Doherty amplifier. As an example, for a given parasitic capacitance of 4.6 pF and a target optimum load of 15 Ohm, the load return loss S_lp can be obtained using a traditional output network (702) and the disclosed network (704) for a center operating frequency of 3.75 GHz, as shown in FIG. 7A, and the output return loss S_out can be obtained using a traditional output network (706) and the disclosed network (708) as shown in FIG. 7B.

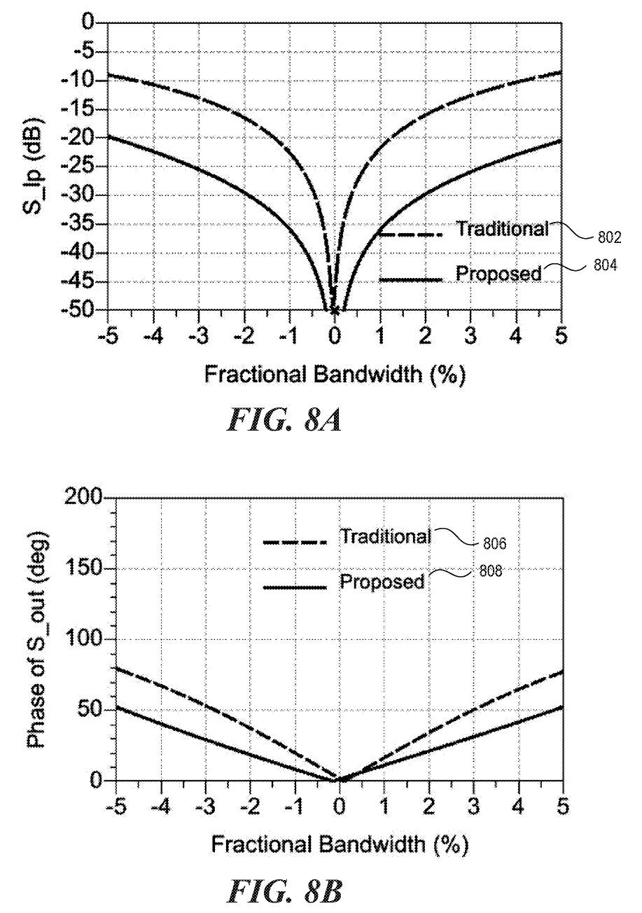

FIGS. 8A and 8B show the bandwidth difference between a traditional output network and a network for a peaking branch with center frequency of 10 GHz that could be implemented as part of a three-stage, dual-drive Doherty amplifier. As an example, for a given parasitic capacitance of 4.6 pF and target optimum load of 15 Ohm, the load return loss S_lp can be obtained using a traditional output network (802) and the disclosed network (804) for center operating frequency of 10 GHz as shown in FIG. 8A, and the output return loss S_out can be obtained using a traditional output network (806) and the disclosed network (808) as shown in FIG. 8B.

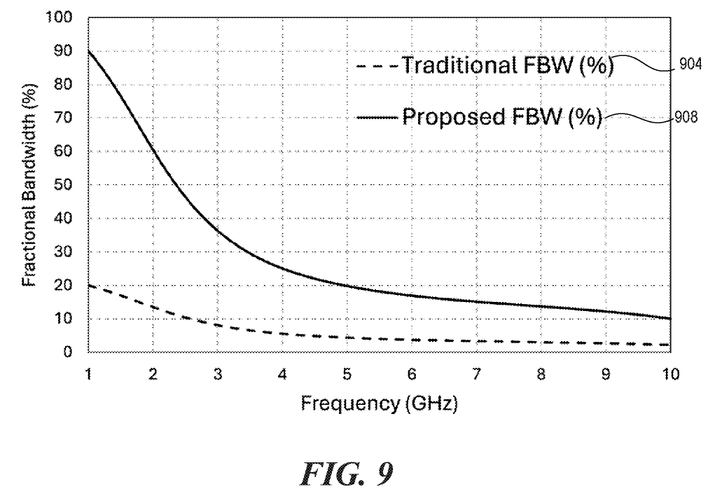

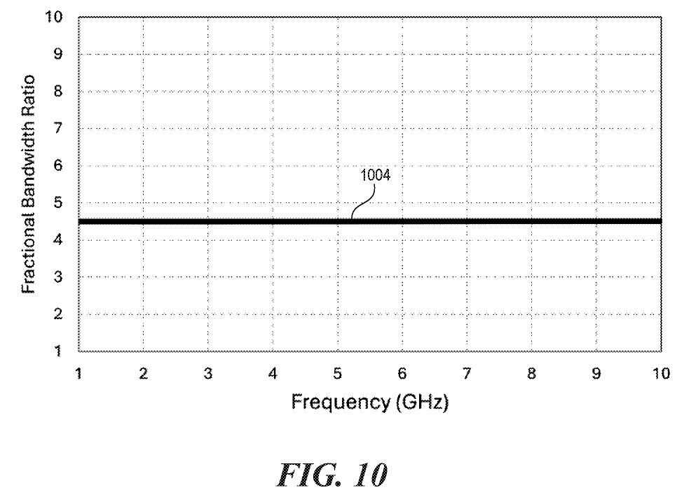

FIG. 9 plots the fractional bandwidth versus frequency for a traditional output network and for a network that could be implemented as part of a three-stage, dual-drive Doherty amplifier. FIG. 10 shows the fractional bandwidth ratio (1004) between a traditional output network and a network that could be implemented as part of a three-stage, dual-drive Doherty amplifier. The fractional bandwidth (FBW) is defined as the bandwidth where the transformed load return loss (S_lp) is less than -20 dB and the output return phase (S_out) is within +-50 degrees. As shown in FIG. 9, the FBW 908 of the disclosed network is typically larger than the FBW 904 of a traditional network. As shown in FIG. 10, the ratio (1004) of the FBW of the disclosed network and the FBW of a traditional network is 4.5 regardless of the operating frequency.

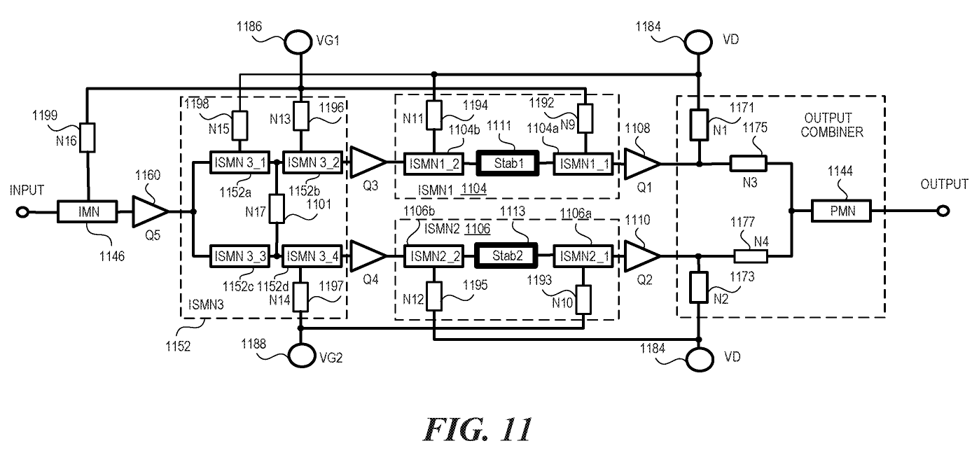

One example of a three-stage, dual-drive topology for a Doherty amplifier (1100) is shown in FIG. 11. The matching networks – that is, input matching network IMN (1102), interstage matching network ISMN1 (1104), interstage matching network ISMN2 (1106), interstage matching network ISMN3 (1108), and the output combiner circuit (1110) – can be realized with transmission lines and/or lumped components, like inductors, capacitors, or resistors. The output combiner circuit (1110) may have the topology shown in FIGS. 3 and 4, for example. Note that, in some embodiments, the stability circuits Stab1 (1112), Stab 2 (1114) are inserted into interstage matching network ISMN1 (1104) and/or interstage matching network ISMN2 (1106), respectively, to reenforce the stability of the entire circuit. The stability circuits Stab1 (1112), Stab2 (1114) can be realized with lossy circuits, such as parallel RC networks. Interstage matching network ISMN3 (1108) between the pre-driver cell Q5 (1116) and driver cells Q3 (1118), Q4 (1120) may act as an impedance transformer, power divider, and phase adjuster. Conventionally, this part of the circuit may have been composed of interstage matching networks, an offset line, and a power divider – which collectively would occupy a relatively large amount of space. With the topology shown in FIG. 11, the circuit can realize the power dividing and phase offsetting functions in the matching network. As shown in FIG. 11, an isolator network N17 (1122) could be added in a proper position to improve the isolation between the two branches of the circuit.

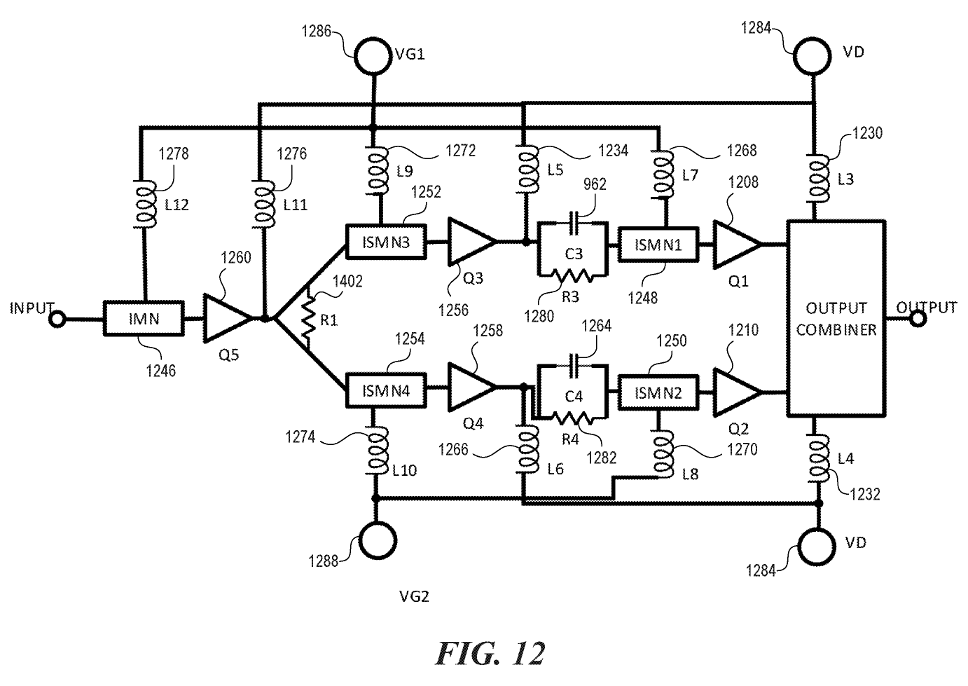

FIG. 12, meanwhile, shows another example of a three-stage, dual-drive topology for a Doherty amplifier (1200) in which the biasing network, isolating network, and stability network are implemented using lumped components. As shown in FIG. 12, the carrier branch can include a carrier driver stage including an active device Q3 (1256), an interstage matching network ISMN3 (1252) at the input of the network, and an interstage matching network ISMN1 (1248) at the output of the network. The drain of active device Q3 (1256) can be biased with DC voltage VD (1284) through inductor L5 (1234). In some embodiments, the drain of active device Q1 (1208) can be biased with the same DC voltage VD (1284) through L3 (1230). The input gate of active device Q3 (1256) and the input gate of active device Q1 (1208) can be biased with the same voltage VG1 (1286) through inductor L9 (1272) and L7 (1268), respectively. A feedback loop can be introduced due to the sharing of biasing components, leading to potential oscillation specially at low frequency. Thus, in some embodiments, a parallel resistor R3 (1280) and capacitor C3 (1262) circuit are inserted between the carrier driver stage and the peaking driver stage to improve the stability of the carrier branch.

Similar to the carrier branch, a peaking driver stage can include an active device Q4 (1258), an interstage matching network ISMN4 (1254) coupled to the input of the network, and an interstage matching network ISMN2 (1250) coupled to the output of the network can be added before active device Q2 (1210). In some embodiments, the aforementioned components can share the same gate biasing DC voltage VG2 (1288) through inductor L8 (1270) and L9 (1272), respectively. A drain biasing supply VD (1284) can further be shared by active device Q4 (1258) and active device Q2 (1210) through inductors L6 (1266) and L4 (1232), respectively. In some embodiments, an RC circuit including resistor R4 (1282) and capacitor C4 (1264) can be inserted in between the aforementioned components to reinforce the stability of the peaking branch. Since the peaking driver doesn’t consume power at power back-off, the efficiency of the dual-drive Doherty amplifier is higher than that of the single-drive Doherty amplifier.

As shown in FIG. 12, the pre-driver cell Q5 (1260) may have the input matching network IMN (1246) at its input and power splitter at its output. The input of the pre-driver cell Q5 (1260) may be biased with DC voltage VG1 (1286) through inductor L12 (1278), while the output of the pre-driver cell Q5 (1260) may be biased with DC voltage VD (1284) through inductor L11 (1276). The isolator in the power splitter can be realized with a resistor (1202). To decrease the size of the circuit, the power splitter plus the interstage matching networks ISMN3 (1252) and ISMN4 (1254) can be realized with a single interstage matching network ISMN3 as shown in FIG. 11.

In some embodiments, to reduce the size and cost of the circuit, a quasi-MMIC hybrid design can be implemented for the dual-drive Doherty amplifier. The active devices Q1 (1208) – Q5 (1260) can be implemented based on a GaN process, which has higher power density and a more-compact size. A passive portion including the output combiner circuit, interstage matching networks ISMN1 (1248) – ISMN4 (1254), and the input power divider can be implemented using GaAs, silicon, or another substrate material that has a more compact size and a relatively lower cost. In some embodiments, the active parts can be connected to the passive parts with bonding wires. In some embodiments, all the chips can share the same package.

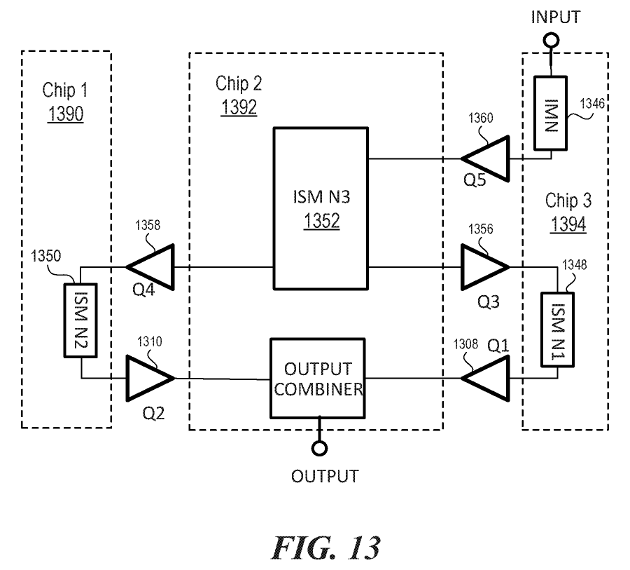

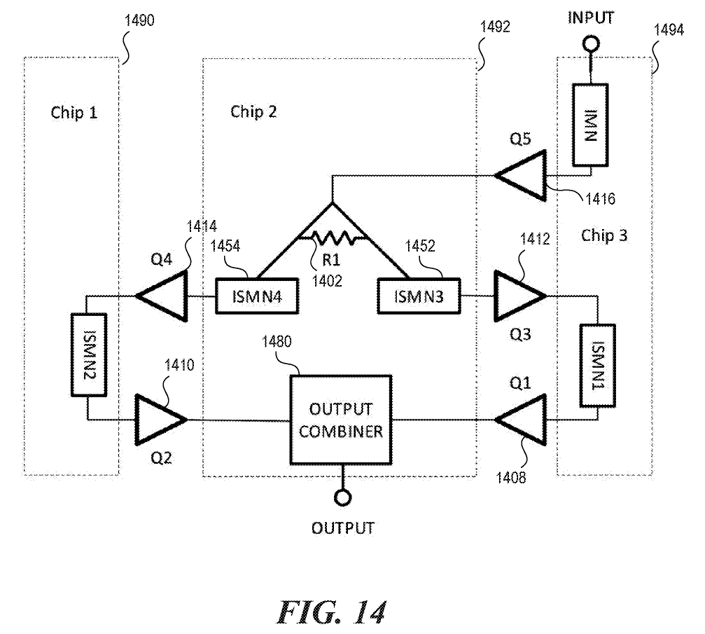

To further reduce the size of the circuit, the location of the active parts and passive parts could be even further reorganized as shown in FIGS. 13 and 14. FIG. 13 shows an example layout distribution of a compact three-stage, dual-drive Doherty amplifier, while FIG. 14 shows another example layout distribution of a compact three-stage, dual-drive Doherty amplifier.

Referring to FIG. 13, the input matching network IMN (1302), interstage matching networks ISMN1 (1304), ISMN2 (1306), and/or ISMN3 (1308), output combiner circuit (1310), and input power divider could be located on the same chip or separate chips. Here, for example, interstage matching network ISMN2 (1306) is located on a first chip (1390), interstage matching network ISMN3 and the output combiner circuit (1310) are located on a second chip (1392), and the input matching network IMN (1302) and interstage matching network ISMN1 (1304) are located on a third chip (1394). Moreover, the high-power carrier active device Q1 (1312) and peaking active device Q2 (1314) may be separated by a threshold distance to reduce the mutual heating effect between those devices, thereby resulting in a lower operating temperature than a traditional design.

FIG. 14 shows another example layout distribution that exhibits several of the same benefits as the example layout distribution shown in FIG. 13. Again, the interstage matching networks ISMN3 (1452), ISMN4 (1454), output combiner circuit (1480), and the input power divider including the resistor R1 (1402) can be implemented on the same chip rather than on separate chips. The high-power carrier active device Q1 (1408) and peaking active device Q2 (1410) can again be separated by the threshold distance to reduce the mutual heating effect and achieve lower operating temperature.

In FIGS. 13 and 14, the high-power carrier active device Q1 (1312, 1408), peaking active device Q2 (1314, 1410), carrier driver cell Q3 (1316, 1412), peaking driver cell Q4 (1318, 1414), and pre-driver cell Q5 (1320, 1416) are not shown as necessarily being associated with any of the chips – that is, Chip 1 (1390, 1490), Chip 2 (1392, 1492), or Chip 3 (1394, 1494). These cells – referred to as “Q1,” “Q2”, “Q3”, “Q4,” and “Q5” for convenience – could be located among the chips to achieve different benefits. For example, Q1 (1312, 1408), Q3 (1316, 1412), and Q5 (1320, 1416) could be implemented in one chip (e.g., Chip 2 or Chip 3) while Q2 (1314, 1410) and Q4 (1318, 1414) could be implemented in another chip (e.g., Chip 1 or Chip 2) to reduce the complexity of package assembly. As another example, Q1 (1312, 1408) and Q3 (1316, 1412) could be implemented in a first chip (e.g., Chip2), Q5 (1320, 1416) could be implemented in a second chip (e.g., Chip3), and Q2 (1314, 1410) and Q4 (1318, 1414) could be implemented in a third chip (e.g., Chip 1). Alternatively, Q1 (1312, 1408), Q2 (1314, 1410), Q3 (1316, 1412), Q4 (1318, 1414), and Q5 (1320, 1416) could each be implemented in a separate chip to increase flexibility in design and implementation. Accordingly, these components can be distributed among the various chips in different ways, depending on the desired results and complexity – or simplicity – in design.

### Overview of Dual-Stage Doherty Amplifier and Benefits Thereof

Accordingly, the dual-drive Doherty amplifier introduced here not only offers improved power consumption through selective activation of amplifier stages, but also offers modularity and flexibility in the design and implementation. In sum, the power amplifier circuit can include a peaking amplifier branch including a peaking driver cell coupled to a peaking power amplifier cell via a second interstage matching network. The peaking driver cell can be configured to regulate a second current flowing through the peaking power amplifier cell. The power amplifier circuit can include a pre-driver cell coupled to the carrier driver cell via a third interstage matching network and to the peaking driver cell via a fourth interstage matching network. In operation, the pre-driver cell acts like a gain block along the peaking amplifier branch by multiplying its input by a constant value or gain. The power amplifier circuit can include an interstage power divider matching network coupled to the carrier amplifier branch and the peaking amplifier branch. The interstage power divider matching network can be configured to divide an RF signal that is input to the power amplifier circuit, between the carrier amplifier branch and the peaking amplifier branch. The power amplifier circuit can include an output combiner circuit coupled to the carrier amplifier branch and the peaking amplifier branch. The output combiner circuit can be configured to combine output signals from the carrier power amplifier cell and the peaking power amplifier cell to provide an amplified version of the RF signal. In some embodiments, the output combiner circuit absorbs the effect of the parasitic capacitance.

In some embodiments of the power amplifier circuit, each of the carrier driver cell, the carrier power amplifier cell, the peaking driver cell, and the peaking power amplifier cell can include at least one GaN transistor. In some embodiments of the power amplifier circuit, each of the first, second, third, and fourth interstage matching networks are passive networks that are implemented with GaAs, silicon, or another suitable substrate material. Accordingly, the carrier driver cell, carrier power amplifier cell, peaking driver cell, and/or peaking power amplifier cell could be GaN devices, GaAs devices, or even laterally diffused metal-oxide-semiconductor (LDMOS) devices or complementary metal-oxide-semiconductor (CMOS) devices.

The output combiner circuit can include a first biasing network coupled to the carrier power amplifier cell in a shunt configuration, a second biasing network coupled to the peaking power amplifier cell in a shunt configuration, a third network coupled to the carrier power amplifier cell in a series configuration, a fourth network coupled to the peaking power amplifier cell in a series configuration, and a fifth post-matching network. These networks can be realized with a single inductor, single transmission line, single capacitor, or a more sophisticated combination of circuit components.

In some embodiments of the power amplifier circuit, the first interstage matching network includes a first reinforced stability circuit including a first resistor and a first capacitor connected in parallel. The second interstage matching network can include a second reinforced stability circuit including a second resistor and a second capacitor connected in parallel. The carrier power amplifier cell and the carrier driver cell can share a first gate biasing voltage supply, the peaking power amplifier cell and the peaking driver cell can share a second gate biasing voltage supply, and the power amplifier circuit can include multiple transistors that share a drain biasing voltage supply.

In some embodiments, the power amplifier circuit can include an input matching network configured to receive the RF signal. The input matching network can be coupled to the pre-driver cell.

In some embodiments, the power amplifier circuit includes a third interstage matching network that is a power dividing matching network. The third interstage matching network can provide impedance matching, power dividing, and phase aligning functionalities. The interstage power dividing network can be located between the pre-driver cell and driver cells.

In some embodiments, the power amplifier circuit includes an interstage power dividing network, a third interstage matching network, and a fourth interstage matching network between the pre-driver cell and driver cells.

In some embodiments, the interstage power dividing network and the output combiner circuit can be implemented on a first chip. The input matching network and the first interstage matching network can be implemented on a second chip. The second interstage matching network can be implemented on a third chip. In some embodiments of the power amplifier circuit, the power amplifier circuit can include multiple transistors, and each of the multiple transistors can be implemented on a respective GaN chip. The power amplifier circuit can be configured to receive the RF signal from a small cell base station of a telecommunications network. A small cell base station is a low-powered radio access node that can provide cellular coverage to an area with a radius ranging between a few feet to a few kilometers. Small cell base stations, due to their smaller size and coverage footprint, have low power consumption and cost compared to macro base stations. Small cell base stations can employ power amplifier circuits to amplify locally generated radio signals for transmission or to amplify radio signals received from distant transmitters. Accordingly, the power amplifying circuit described here – when implemented in a telecommunications device, such as a mobile phone, tablet computer, laptop computer, router, or the like – may be used to amplify a radio signal that is received from a source external to the telecommunications device. In some embodiments, the power amplifier circuit is further configured to supply the amplified signal to an antenna of the telecommunications device for transmission to a destination that is also external to the telecommunications device.

### Examples

1. A power amplifier circuit comprising:

a carrier amplifier branch that includes a carrier driver cell that is coupled to a carrier power amplifier cell via a first interstage matching network and that is configured to regulate a first current flowing through the carrier power amplifier cell;

a peaking amplifier branch that includes a peaking driver cell that is coupled to a peaking power amplifier cell via a second interstage matching network and that is configured to regulate a second current flowing through the peaking power amplifier cell;

a pre-driver cell that is coupled to the carrier driver cell and to the peaking driver cell via a third interstage matching network and that is configured to act as a gain block;

an interstage power dividing network that is coupled to the carrier amplifier branch and to the peaking amplifier branch and that is configured to divide an RF signal output by the pre-driver cell; and

an output combiner circuit that is coupled to the carrier amplifier branch and to the peaking amplifier branch and that is configured to combine a first output produced by the carrier power amplifier cell with a second output produced by the peaking power amplifier cell to provide an amplified version of the RF signal.

2. The power amplifier circuit of example 1, wherein the output combiner circuit is configured to absorb parasitic capacitance from the carrier power amplifier cell and from the peaking power amplifier cell.

3. The power amplifier circuit of example 1, wherein the output combiner circuit comprises:

a first biasing component that is coupled to the carrier power amplifier cell in a shunt configuration,

a second biasing component that is coupled to the peaking power amplifier cell in a shunt configuration,

a third component that is coupled to the carrier power amplifier cell in a series configuration,

a fourth component that is coupled to the peaking power amplifier cell in a series configuration, and

a post-matching network that is coupled to the first biasing component and to the second biasing component and that is configured to transform loads received from the first and second biasing components to a target load impedance.

4. The power amplifier circuit of example 3,

wherein the first biasing component is an inductor or a transmission line,

wherein the second biasing component is an inductor or a transmission line,

wherein the third component is an inductor or a transmission line, and

wherein the fourth component is a capacitor.

5. The power amplifier circuit of example 1, wherein the peaking power amplifier cell has a larger active device than the carrier power amplifier cell.

6. The power amplifier circuit of example 1,

wherein the carrier power amplifier cell, the carrier driver cell, and the pre-driver cell share a first gate biasing voltage supply through DC biasing networks,

wherein the peaking power amplifier cell and the peaking driver cell share a second gate biasing voltage supply through DC biasing networks, and

wherein the power amplifier circuit further comprises multiple transistors that share a drain biasing voltage supply through DC biasing networks.

8. The power amplifier circuit of example 1, wherein the third interstage matching network is a power dividing matching network that offers power dividing, phase aligning and impedance matching functionalities.

9. The power amplifier circuit of example 1,

wherein the input matching network and the first interstage matching network are implemented on a first integrated circuit,

wherein the second interstage matching network is implemented on a second integrated circuit, and

wherein the third interstage matching network, the interstage power dividing network, and the output combiner circuit are implemented on a third integrated circuit.

10. The power amplifier circuit of example 1, wherein each of the pre-driver cell, the carrier driver cell, the carrier power amplifier cell, the peaking driver cell, and the peaking power amplifier cell is representative of a GaN device, a GaAs device, a LDMOS device, or a CMOS device.

11. The power amplifier circuit of example 1,

wherein the pre-driver cell, the carrier driver cell and the carrier PA cell can be implemented on one integrated circuit or respective integrated circuits, and

where in the peaking driver cell and the peaking PA cell can be implemented on one integrated circuit or respective integrated circuits.

12. The power amplifier circuit of example 1, wherein each of the first, second, and third interstage matching networks includes one or more passive circuit components that comprise GaAs or silicon or any other suitable substrate material.

13. The power amplifier circuit of example 1, wherein the first interstage matching network comprises a first reinforced stability circuit that includes a first resistor and a first capacitor connected in parallel.

14. The power amplifier circuit of example 13, wherein the second interstage matching network comprises a second reinforced stability circuit that includes a second resistor and a second capacitor connected in parallel.

15. The power amplifier circuit of example 1, further comprising:

an input matching network that is coupled to the pre-driver cell and that is configured to receive the RF signal and transfer the RF signal to the pre-driver cell.

16. A power amplifier circuit comprising:

a first driver cell that is coupled to a first amplifier cell via a first interstage matching network and that is configured to regulate current flowing to the first amplifier cell;

a second driver cell that is coupled to a second amplifier cell via a second interstage matching network and that is configured to regulate current flowing to the second amplifier cell;

a pre-driver cell that is coupled to the first and second driver cells via a third interstage matching network and that is configured to act as a gain block by multiplying an input RF signal by a constant value to produce an output RF signal that is directed to the third interstage matching network; and

an output combiner circuit that is configured to combine a first output that is produced by the first amplifier cell with a second output that is produced by the second amplifier cell, so as to provide an amplified version of the input RF signal.

17. A telecommunications device comprising:

a carrier amplifier branch that includes a carrier driver cell that is coupled to a carrier power amplifier cell,

wherein the carrier driver cell is configured to regulate a first current flowing through the carrier power amplifier cell;

a peaking amplifier branch that includes a peaking driver cell that is coupled to a peaking power amplifier cell,

wherein the peaking driver cell is configured to regulate a second current flowing through the peaking power amplifier cell;

a pre-driver cell that is coupled to the carrier driver cell and to the peaking driver cell and that is configured to act as a gain block;

an input matching network that is coupled to the carrier amplifier branch and the peaking amplifier branch,

wherein the input matching network is configured to divide an RF signal, received by the telecommunications device from a source external to the telecommunications device, between the carrier amplifier branch and the peaking amplifier branch; and

an output combiner circuit that is coupled to the carrier amplifier branch and to the peaking amplifier branch,

wherein the output combiner circuit is configured to combine signals output by the carrier power amplifier cell and the peaking power amplifier cell to produce an amplified version of the RF signal.

18. The telecommunications device of example 17, wherein the output combiner circuit is configured to absorb parasitic capacitance from the carrier power amplifier cell and from the peaking power amplifier cell.

19. The telecommunications device of example 17,

wherein the carrier driver cell is coupled to the carrier power amplifier cell via a first interstage matching network, and

wherein the peaking driver cell is coupled to the peaking power amplifier cell via a second interstage matching network.

20. The telecommunications device of example 19, wherein the pre-driver cell is coupled to the carrier driver cell and to the peaking driver cell via a third interstage matching network.

21. The telecommunications device of example 20,

wherein the input matching network, the third interstage matching network, and the first interstage matching network are coupled, via respective inductors, to a first gate biasing voltage supply, and

wherein the third interstage matching network and the second interstage matching network are coupled, via respective inductors, to a second gate biasing voltage supply.

22. The telecommunications device of example 21, wherein the third interstage matching network, the second interstage matching network, the first interstage matching network, and the output combiner circuit are coupled, via respective inductors, to a drain biasing voltage supply.

### Terminology

References in the present disclosure to “an embodiment” or “some embodiments” mean that the feature, function, structure, or characteristic being described is included in at least one embodiment. Occurrences of such phrases do not necessarily refer to the same embodiment, nor are they necessarily referring to alternative embodiments that are mutually exclusive of one another.

Unless the context clearly requires otherwise, the terms “comprise,” “comprising,” and “comprised of” are to be construed in an inclusive sense rather than an exclusive or exhaustive sense. That is, in the sense of “including but not limited to.” The term “based on” is also to be construed in an inclusive sense. Thus, the term “based on” is intended to mean “based at least in part on.”

The terms “connected,” “coupled,” and variants thereof are intended to include any connection or coupling between two or more elements, either direct or indirect. The connection or coupling can be physical, logical, or a combination thereof. For example, elements may be electrically or communicatively coupled to one another despite not sharing a physical connection.

When used in reference to a list of multiple items, the word “or” is intended to cover all of the following interpretations: any of the items in the list, all of the items in the list, and any combination of items in the list.

### Remarks

The foregoing description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe the principles of the invention and its practical applications, thereby enabling those skilled in the relevant art to understand the claimed subject matter, the various embodiments, and the various modifications that are suited to the particular uses contemplated.

Although the Detailed Description describes certain embodiments and the best mode contemplated, the technology can be practiced in many ways no matter how detailed the Detailed Description appears. Embodiments can vary considerably in their implementation details, while still being encompassed by the specification. Particular terminology used when describing certain features or aspects of various embodiments should not be taken to imply that the terminology is being redefined herein to be restricted to any specific characteristics, features, or aspects of the technology with which that terminology is associated. In general, the terms used in the following claims should not be construed to limit the technology to the specific embodiments disclosed in the specification, unless those terms are explicitly defined herein. Accordingly, the actual scope of the technology encompasses not only the disclosed embodiments, but also all equivalent ways of practicing or implementing the embodiments.

The language used in the specification has been principally selected for readability and instructional purposes. It may not have been selected to delineate or circumscribe the subject matter. It is therefore intended that the scope of the technology be limited not by this Detailed Description, but rather by any claims that issue on an application based hereon. Accordingly, the disclosure of various embodiments is intended to be illustrative, but not limiting, of the scope of the technology as set forth in the following claims.

We claim:

1. A power amplifier circuit comprising:
a carrier amplifier branch that includes a carrier driver cell that is coupled to a carrier power amplifier cell via a first interstage matching network and that is configured to regulate a first current flowing through the carrier power amplifier cell;
a peaking amplifier branch that includes a peaking driver cell that is coupled to a peaking power amplifier cell via a second interstage matching network and that is configured to regulate a second current flowing through the peaking power amplifier cell;
a pre-driver cell that is coupled to the carrier driver cell and to the peaking driver cell via a third interstage matching network and that is configured to act as a gain block;
an interstage power dividing network that is coupled to the carrier amplifier branch and to the peaking amplifier branch and that is configured to divide a radio-frequency (RF) signal output by the pre-driver cell; and
an output combiner circuit that is coupled to the carrier amplifier branch and to the peaking amplifier branch and that is configured to combine a first output produced by the carrier power amplifier cell with a second output produced by the peaking power amplifier cell to provide an amplified version of the RF signal.

2. The power amplifier circuit of claim 1, wherein the output combiner circuit is configured to absorb parasitic capacitance from the carrier power amplifier cell and from the peaking power amplifier cell.

3. The power amplifier circuit of claim 1, wherein the output combiner circuit comprises:
a first biasing component that is coupled to the carrier power amplifier cell in a shunt configuration,
a second biasing component that is coupled to the peaking power amplifier cell in a shunt configuration,
a third component that is coupled to the carrier power amplifier cell in a series configuration,
a fourth component that is coupled to the peaking power amplifier cell in a series configuration, and
a post-matching network that is coupled to the first biasing component and to the second biasing component and that is configured to transform loads received from the first and second biasing components to a target load impedance.

4. The power amplifier circuit of claim 3,
wherein the first biasing component is an inductor or a transmission line,
wherein the second biasing component is an inductor or a transmission line,
wherein the third component is an inductor or a transmission line, and
wherein the fourth component is a capacitor.

5. The power amplifier circuit of claim 1, wherein the peaking power amplifier cell has a larger active device than the carrier power amplifier cell.

6. The power amplifier circuit of claim 1,
wherein the carrier power amplifier cell, the carrier driver cell, and the pre-driver cell share a first gate biasing voltage supply through DC biasing networks,
wherein the peaking power amplifier cell and the peaking driver cell share a second gate biasing voltage supply through DC biasing networks, and
wherein the power amplifier circuit further comprises multiple transistors that share a drain biasing voltage supply through DC biasing networks.

7. The power amplifier circuit of claim 6, wherein all of the DC biasing networks are implemented with inductors, transmission lines, and/or resistors.

8. The power amplifier circuit of claim 1, wherein the third interstage matching network is a power dividing matching network that offers power dividing, phase aligning and impedance matching functionalities.

9. The power amplifier circuit of claim 1,
wherein the input matching network and the first interstage matching network are implemented on a first integrated circuit,
wherein the second interstage matching network is implemented on a second integrated circuit, and
wherein the third interstage matching network, the interstage power dividing network, and the output combiner circuit are implemented on a third integrated circuit.

10. The power amplifier circuit of claim 1, wherein each of the pre-driver cell, the carrier driver cell, the carrier power amplifier cell, the peaking driver cell, and the peaking power amplifier cell is representative of a gallium nitride (GaN) device, gallium arsenide (GaAs) device, a laterally diffused metal-oxide-semiconductor (LDMOS) device or a complementary metal-oxide-semiconductor (CMOS) device.

11. The power amplifier circuit of claim 1,
wherein the pre-driver cell, the carrier driver cell and the carrier PA cell can be implemented on one integrated circuit or respective integrated circuits, and
where in the peaking driver cell and the peaking PA cell can be implemented on one integrated circuit or respective integrated circuits.

12. The power amplifier circuit of claim 1, wherein each of the first, second, and third interstage matching networks includes one or more passive circuit components that comprise gallium arsenide (GaAs) or silicon or any other suitable substrate material.

13. The power amplifier circuit of claim 1, wherein the first interstage matching network comprises a first reinforced stability circuit that includes a first resistor and a first capacitor connected in parallel.

14. The power amplifier circuit of claim 13, wherein the second interstage matching network comprises a second reinforced stability circuit that includes a second resistor and a second capacitor connected in parallel.

15. The power amplifier circuit of claim 1, further comprising:
an input matching network that is coupled to the pre-driver cell and that is configured to receive the RF signal and transfer the RF signal to the pre-driver cell.

16. A power amplifier circuit comprising:
a first driver cell that is coupled to a first amplifier cell via a first interstage matching network and that is configured to regulate current flowing to the first amplifier cell;
a second driver cell that is coupled to a second amplifier cell via a second interstage matching network and that is configured to regulate current flowing to the second amplifier cell;
a pre-driver cell that is coupled to the first and second driver cells via a third interstage matching network and that is configured to act as a gain block by multiplying an input radio-frequency (RF) signal by a constant value to produce an output RF signal that is directed to the third interstage matching network; and
an output combiner circuit that is configured to combine a first output that is produced by the first amplifier cell with a second output that is produced by the second amplifier cell, so as to provide an amplified version of the input RF signal.

17. A telecommunications device comprising:
a carrier amplifier branch that includes a carrier driver cell that is coupled to a carrier power amplifier cell,
wherein the carrier driver cell is configured to regulate a first current flowing through the carrier power amplifier cell;
a peaking amplifier branch that includes a peaking driver cell that is coupled to a peaking power amplifier cell,
wherein the peaking driver cell is configured to regulate a second current flowing through the peaking power amplifier cell;
a pre-driver cell that is coupled to the carrier driver cell and to the peaking driver cell and that is configured to act as a gain block;
an input matching network that is coupled to the carrier amplifier branch and the peaking amplifier branch,
wherein the input matching network is configured to divide a radio-frequency (RF) signal, received by the telecommunications device from a source external to the telecommunications device, between the carrier amplifier branch and the peaking amplifier branch; and
an output combiner circuit that is coupled to the carrier amplifier branch and to the peaking amplifier branch,
wherein the output combiner circuit is configured to combine signals output by the carrier power amplifier cell and the peaking power amplifier cell to produce an amplified version of the RF signal.

18. The telecommunications device of claim 17, wherein the output combiner circuit is configured to absorb parasitic capacitance from the carrier power amplifier cell and from the peaking power amplifier cell.

19. The telecommunications device of claim 17,
wherein the carrier driver cell is coupled to the carrier power amplifier cell via a first interstage matching network, and
wherein the peaking driver cell is coupled to the peaking power amplifier cell via a second interstage matching network.

20. The telecommunications device of claim 19, wherein the pre-driver cell is coupled to the carrier driver cell and to the peaking driver cell via a third interstage matching network.

21. The telecommunications device of claim 20,
wherein the input matching network, the third interstage matching network, and the first interstage matching network are coupled, via respective inductors, to a first gate biasing voltage supply, and
wherein the third interstage matching network and the second interstage matching network are coupled, via respective inductors, to a second gate biasing voltage supply.

22. The telecommunications device of claim 21, wherein the third interstage matching network, the second interstage matching network, the first interstage matching network, and the output combiner circuit are coupled, via respective inductors, to a drain biasing voltage supply.
